(19) United States
(12) Patent Application Publication
(10) Pub. No.: US 2025/0275205 A1
(43) Pub. Date: Aug. 28, 2025

(54) P-TYPE SPINEL STRUCTURES AS A P-N HETEROEPITAXIAL INTERFACE TO B-GA2O3

(71) Applicant: The Government of the United States of America, as represented by the Secretary of the Navy, Arlington, VA (US)

(72) Inventors: James C. Gallagher, Alexandria, VA (US); Marko J. Tadjer, Vienna, VA (US); Jennifer Hite, Gainsville, FL (US); Michael A. Mastro, Fairfax, VA (US); Adam J. Hauser, Tuscaloosa, AL (US); Babajide Akintunde, Tuscaloosa, AL (US)

(73) Assignee: The Government of the United States of America, as represented by the Secretary of the Navy, Arlington, VA (US)

(21) Appl. No.: 19/058,516

(22) Filed: Feb. 20, 2025

Related U.S. Application Data
(60) Provisional application No. 63/557,011, filed on Feb. 23, 2024.

(51) Int. Cl. H10D 62/82; C30B 23/02; C30B 23/08; C30B 29/22; C30B 29/26; H01L 21/02

(52) U.S. Cl. CPC H10D 62/8271; C30B 23/025; C30B 23/08; C30B 29/22; C30B 29/26; H01L 21/02414; H01L 21/02565; H01L 21/02579; H01L 21/02631

(57) ABSTRACT

Spinel and gallium oxide (Ga₂O₃) p-n heteroepitaxial interfaces and methods of making the same are presented. In embodiments, a method of manufacturing spinel structures includes depositing, via off-axis sputtering, an epitaxial layer of p-type spinel on a gallium oxide (Ga₂O₃) substrate, thereby creating a p-n heteroepitaxial interface between the p-type spinel and the Ga₂O₃ substrate. In implementations, a semiconductor device includes a Ga₂O₃ substrate; a p-type spinel epitaxial layer formed directly on a surface of the Ga₂O₃ substrate, thereby forming a p-n heteroepitaxial interface; and electrodes.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 212050-US2

### BACKGROUND OF THE INVENTION

Aspects of the present invention relate generally to gallium oxide (Ga₂O₃) semiconductor structures and, more particularly, to a method of making spinel/Ga₂O₃ p-n heterojunctions.

One challenge with the development of wide bandgap semiconductor technology is finding effective p and n type dopants. Well-matched dopant pairs are critical to the invention of devices such as diodes, field effect transistors, and bipolar junction transistors. Certain wide-bandgap semiconductors, like diamond, are easily doped p-type, but achieving n-type doping is more challenging. Conversely, semiconductors such as GaN and Ga₂O₃ are often unintentionally n-type doped, while p-type doping proves to be challenging. β-Ga₂O₃ is challenging to dope p-type, but it has advantages over other wide band gap semiconductors including its inexpensive manufacturing cost and large Baliga figure of merit (BFOM). In general, BFOM is a calculation that compares the on-resistance of a material per surface area, which is defined as V_{B}²/Rₒₙ, where V_{B} is the breakdown voltage and Ron is the specific on-resistance.

The lack of p-type doping in a single material can be overcome by creating p-n heterojunctions. In general, a p-n heterojunction is a type of semiconductor junction formed when two different semiconductor materials, one p-type and one n-type, are joined together. P-n heterojunctions have been demonstrated using either nickel (II) oxide (NiO) or copper (I) iodide (CuI as the p-type layer, for example. However, neither NiO or CuI is well lattice matched to Ga₂O₃, and the resultant heterojunction would suffer from scattering due to polycrystalline grain boundaries. With respect to NiO, the lattice mismatch with Ga₂O₃ renders epitaxial growth of a NiO/Ga₂O₃ interface impossible. A close epitaxial match would greatly reduce the grain boundaries and provide a cleaner interface for carrier transfer between layers. Unfortunately, the complex monoclinic structure of β-Ga₂O₃ makes it difficult to find materials for epitaxial growth. Accordingly, there remains a need for improved p-n heterojunction and/or doping solutions for Ga₂O₃ semiconductor structures.

### SUMMARY OF THE INVENTION

In a first aspect of the invention, there is a method of manufacturing spinel structures using off-axis sputtering comprising: depositing, via off-axis sputtering, an epitaxial layer of p-type spinel on a gallium oxide (Ga₂O₃) substrate, thereby creating a p-n heteroepitaxial interface between the p-type spinel and the Ga₂O₃ substrate. In implementations, the p-type spinel is zinc gallate (ZnGa₂O₄), zinc cobalt oxide (ZnCo₂O₄), chromium manganese oxide (Cr₂MnO₄), magnesium aluminate (MgAl₂O₄), or zinc rhodium oxide (Zn Rh₂O₄). In embodiments, the p-type spinel is Cr²MnO₄ doped with lithium (Li) or chromium (Cr). The epitaxial layer may have o thickness between 5 nm and 500 nm. The Ga₂O₃ substrate may have a thickness between 100 μm and 600 μm. In implementations, the off-axis sputtering is performed in an argon and oxygen atmosphere.

In another aspect of the invention, there is a spinel and Ga₂O₃ p-n heteroepitaxial interface including an epitaxial layer of p-type spinel grown directly on a surface of a Ga₂O₃ substrate via off-axis sputtering. The p-type spinel may be ZnGa₂O₄, ZnCo₂O₄, Cr₂MnO₄, MgAl₂O₄, or Zn Rh₂O₄. In implementations, the spinel is Cr₂MnO₄ doped with Li or Cr. In embodiments, the epitaxial layer has a thickness of between 5 nm and 500 nm. In implementations, the Ga₂O₃ substrate has a thickness between 100 μm and 600 μm.

In another aspect of the invention, there is a semiconductor device including: a Ga₂O₃ substrate; a p-type spinel epitaxial layer formed directly on a surface of the Ga₂O₃ substrate, thereby forming a p-n heteroepitaxial interface; and electrodes. In implementations, the p-type spinel is ZnGa₂O₄, ZnCo₂O₄, Cr₂MnO₄, MgAl₂O₄, or Zn Rh₂O₄. In embodiments, the spinel is Cr₂MnO₄ doped with Li or Cr. The semiconductor device may be a transistor. In embodiments, the epitaxial layer has a thickness of between 5 nm and 500 nm. In implementations, the Ga₂O₃ substrate has a thickness between 100 μm and 600 μm.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1A depicts a crystal lattice of Ga₂O₃ in a (−2,0,1) plane compared to an (1,1,1) plane of a spinel structure.

FIG. 1B depicts hexagonal structures present in the crystal lattice of Ga₂O₃ and spinel structure of FIG. 1A.

FIG. 2A depicts an exemplary semiconductor device in accordance with embodiments of the invention.

FIG. 2B depicts another exemplary semiconductor device in accordance with embodiments of the invention.

FIG. 3 depicts an exemplary off-axis sputtering system utilized in accordance with embodiments of the invention.

FIG. 4 shows a flowchart of an exemplary method in accordance with aspects of the present invention.

### DETAILED DESCRIPTION

Aspects of the present invention relate generally to gallium oxide (Ga₂O₃) semiconductor structures and, more particularly, to a method of making spinel/Ga₂O₃ p-n heterojunctions. In implementations, a semiconductor device (a diode, transistor, or other semiconductor device) is made including a p-n heteroepitaxial interface comprising a p-type spinel and a Ga₂O₃ layer (e.g., Ga₂O₃ substrate, or Ga₂O₃ layer on a substrate). In implementations, the spinel is deposited on the Ga₂O₃ utilizing off-axis sputtering (e.g., off-axis magnetron sputtering).

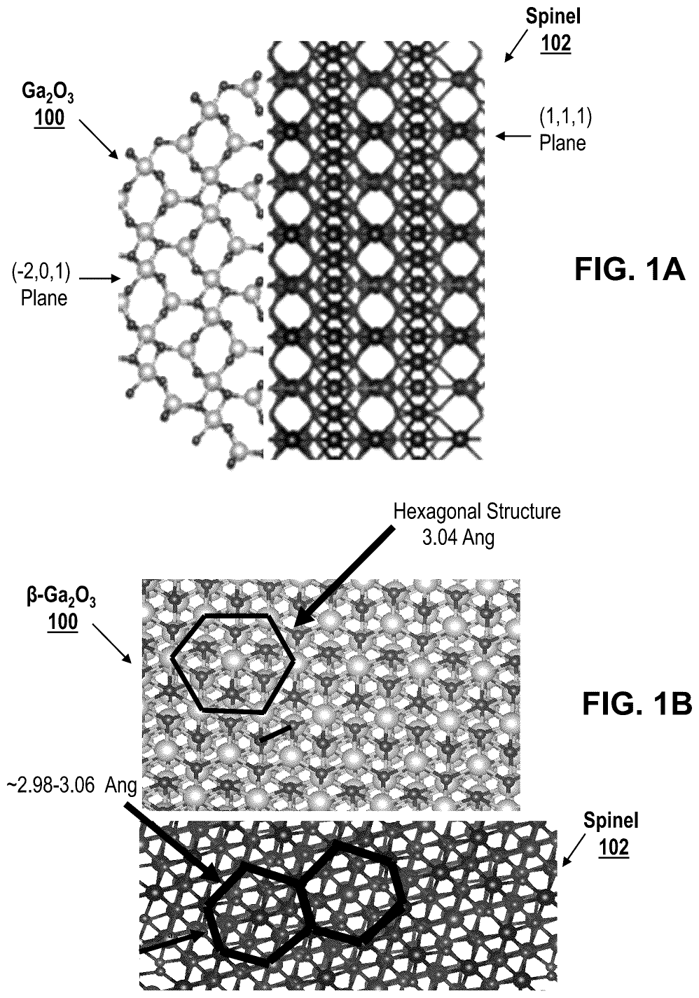

FIG. 1A depicts a crystal lattice 100 of Ga₂O₃ in a (−2,0,1) plane compared to an (1,1,1) plane of a spinel structure 102. As noted above, the complex monoclinic structure of Ga₂O₃ makes it difficult to find materials for epitaxial growth that are well lattice-matched to Ga₂O₃. Examination of the (−2,0,1) plane of Ga₂O₃ reveals a hexagon pattern of Ga atoms with a 3.04 Å side length. This matches well with the (1,1,1) plane of spinel structures having a hexagonal pattern. In embodiments, spinel materials are selected from zinc gallate (ZnGa₂O₄), zinc cobalt oxide (ZnCo₂O₄), chromium manganese oxide (Cr₂MnO₄), magnesium aluminate (MgAl₂O₄), and zinc rhodium oxide (Zn Rh₂O₄). Cr₂MnO₄, is of particular interest because doping the material with lithium (Li) or chromium (Cr) has demonstrated p-type behavior, allowing for control of doping. This allows for epitaxial growth to fabricate a p-n junction. These spinel materials can be used in the p-n junction, and the doping control of the p-layer can be controlled by adjusting the Li and/or Cr doping levels.

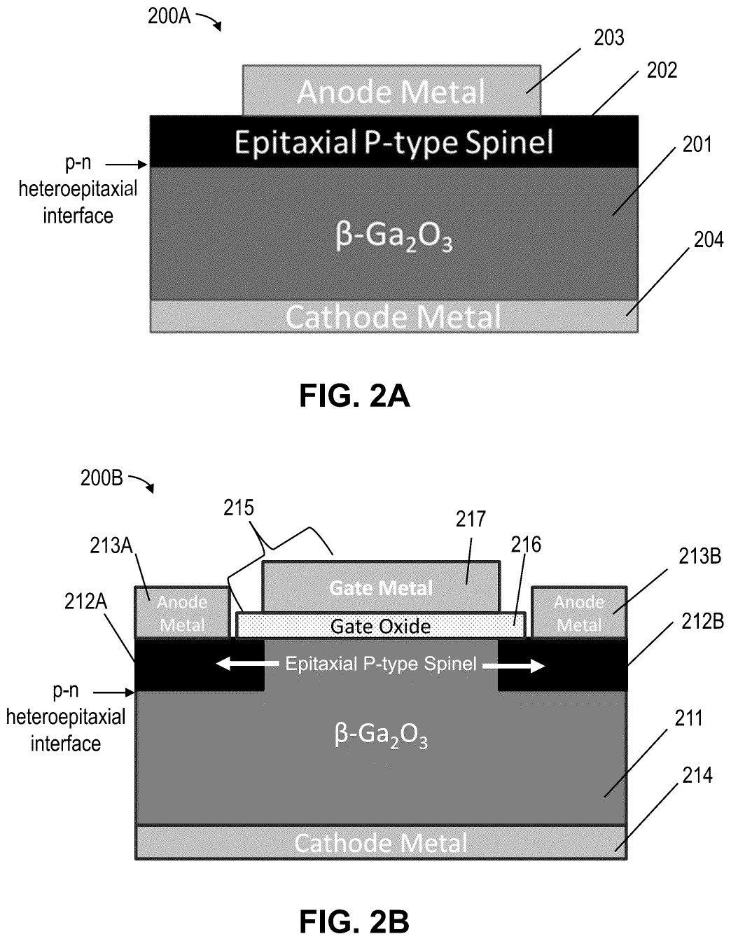

FIG. 1B depicts hexagonal structures present in the crystal lattice 100 of Ga₂O₃ and spinel structure 102 of FIG. 2A. Implementations of the invention utilize (−2,0,1) β-Ga2O₃/(1,1,1) spinel growth, which may serve as the p-n junction in diodes, field effect transistors, and bipolar junction transistors, for example.

Spinel materials are complex oxides, and synthesis techniques are challenging. Implementations of the invention utilize a unique off-axis, ultra-high vacuum (1×10⁻¹⁰ torr base pressure) magnetron combinatorial sputtering system to deposit the spinel onto a substrate. A specific demonstration resulting in epitaxial thin films of Cr₂MnO₄ fabricated by sputter beam epitaxy in an AJA International, Inc. thin film deposition system, with a base pressure of under ultra-high vacuum conditions, with beam-shaping shutter control and growth rate tuning via quartz crystal microbalance (QCM).

FIG. 2A depicts an exemplary semiconductor device 200A in accordance with embodiments of the invention. In implementations, the semiconductor device 200A is fabricated utilizing a method of the present invention, and includes a substrate of β-Ga₂O₃ 201, an epitaxial p-type spinel layer 202 grown on a surface of the β-Ga₂O₃ 201, an anode 203 formed on a surface of the epitaxial p-type spinel layer 202, and a cathode 204 formed on a surface of the β-Ga₂O₃ 201.

FIG. 2B depicts another exemplary semiconductor device 200B in accordance with embodiments of the invention. In implementations, the semiconductor device 200B is fabricated utilizing a method of the present invention, and includes a substrate of β-Ga₂O₃ 211, epitaxial p-type spinel layers 212A, 212B grown within respective trenches in the β-Ga₂O₃ substrate 211, a source anode 213A and a drain anode 213B formed on a surface of respective epitaxial p-type spinel layers 212A, 212B, a cathode 214 formed on a surface of the β-Ga₂O₃ substrate 211, and a gate electrode 215. In implementations, the gate electrode 215 comprises a gate oxide layer 216 formed over a portion of each of the epitaxial p-type spinel layers 212A, 212B and over an upper surface of the β-Ga₂O₃ substrate 211, and a gate metal 217 formed over the gate oxide 216. The semiconductor device 200B of FIG. 2B thus comprises a transistor.

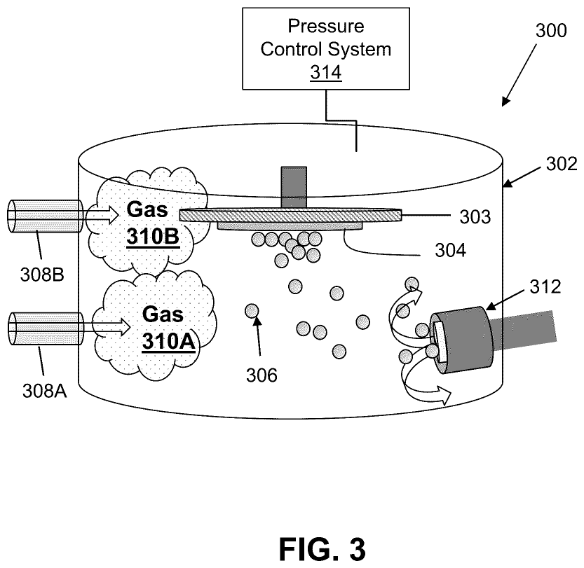

FIG. 3 depicts an exemplary off-axis sputtering system 300 utilized in accordance with embodiments of the invention. In implementations, the system 300 includes a sputtering chamber (vacuum chamber) 302, which provides a controlled epitaxial growth environment. A substrate holder (grounded sample holder) 303 within the sputter chamber 302 is configured to hold a substrate 304 to be coated with a target material represented by the spheres at 306. At least one gas supply line 308A supplies at least a first gas 310A from a gas source (not shown) into the sputtering chamber 302. In implementations, the gas 310A is an inert gas, such as argon, or a mix of an inert gas and oxygen. In embodiments, a second gas supply line 308B provides a second gas 310B from a gas source (not shown) into the sputtering chamber 302. In implementations, the second gas 310B is oxygen, and the first gas 310A is an inert gas. A sputtering gun 312 configured to supply the target material 306 is positioned within the sputtering chamber 302 at an angle (e.g., 90 degrees) with respect to a surface of the substrate 304 to be coated. A pressure control system 314 controls the pressure within the sputtering chamber 302. In use, power is applied to the target material, creating a glow discharge. Atoms of the target material 306 collide with each other and lose energy before reaching and coating the substrate 304 in a thin epitaxial film of the target material 306.

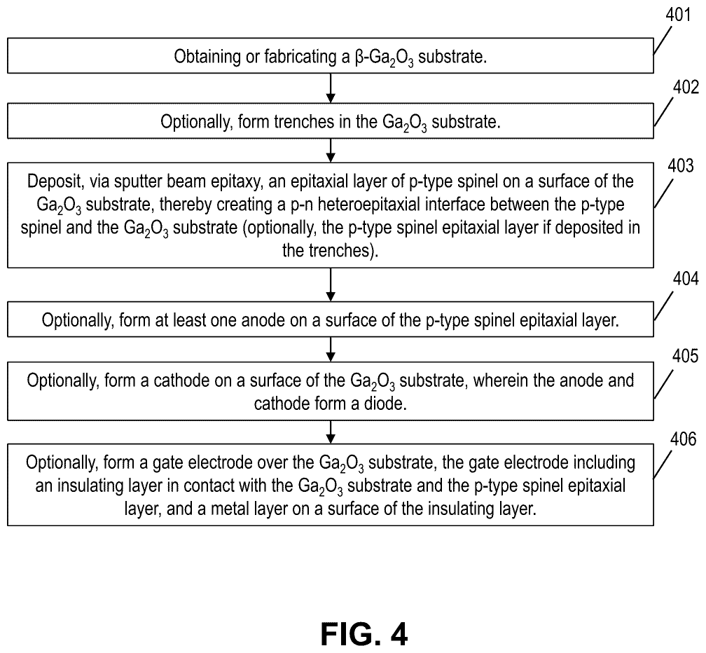

FIG. 4 shows a flowchart of an exemplary method in accordance with aspects of the present invention. FIG. 4 is discussed with reference to elements of FIGS. 2A and 2B, and may be implemented in the environment of FIG. 3.

At 401, a β-Ga₂O₃ substrate (e.g., 201 or 211) is obtained or formed. In implementations, the β-Ga₂O₃ substrate has a thickness of between 100 μm and 600 μm.

Optionally at 402, first and second spaced trenches are formed in the β-Ga₂O₃ substrate (e.g., 211 of FIG. 2B). Existing trenching methods may be utilized at step 402.

At 403, an epitaxial layer of p-type spinel (e.g., 202) is formed on a surface of the Ga₂O₃ substrate (e.g., 201) via off-axis sputtering (e.g., sputter beam epitaxy), thereby creating a p-n heteroepitaxial interface between the p-type spinel and the Ga₂O₃ substrate. See FIG. 2A, for example. In some implementations, the epitaxial layer of p-type spinel comprises layers (e.g., 212A and 212B) deposited into respective trenches formed in the Ga₂O₃ substrate (e.g., 211). See FIG. 2B, for example. In implementations, the epitaxial layer of p-type spinel has a thickness of between 5 nm and 500 nm. In some embodiments, the epitaxial layer of p-type spinel has a thickness of up to 10 μm. In other embodiments, the epitaxial layer of p-type spinel has a thickness of up to 50 μm.

In general, off-axis sputtering is a deposition technique wherein a substrate to be coated with a target material is positioned off-axis with respect to the sputter gun providing the target material. In other words, the supply of target material (sputter gun) is not pointed directly at the center of the substrate or substrate holder. For example, a sputter gun supplying the target material may be positioned at an angle between 20-120 degrees with respect to the substrate. See the example in FIG. 3. In implementation, off-axis magnetron sputtering is used to deposit a spinel onto a Ga₂O₃ substrate.

In a typical sputtering deposition process, a chamber (e.g., 302) is first evacuated to high vacuum (e.g., 1×10⁻¹⁰ torr base pressure) to minimize the partial pressures of background gases and potential contaminants. A sputtering gas comprising the plasma is flowed into the chamber and the total pressure is regulated using a pressure control system (e.g., 314). A high voltage is applied between a cathode (e.g., behind the sputtering target) and an anode (e.g., grounded to the chamber). Electrons in the sputtering gas are accelerated away from the cathode, causing collisions with nearby atoms of sputtering gas and resulting in an electrostatic repulsion which knock off electrons from the sputtering gas atoms, causing ionization. The positive sputter gas atoms accelerate towards the negatively charged cathode, leading to high energy collisions with the surface of the target material. Each collision causes atoms at the surface of the targe material to be ejected (e.g., as atoms 306) into the vacuum environment with enough energy to reach the surface of the substrate to be coated (e.g., 304).

In embodiments, the off-axis sputtering (e.g., sputter beam epitaxy) of step 403 comprises at least the following substeps.

At substep 403A, a Ga₂O₃ substrate (e.g., 304) is placed on a substrate holder (e.g., 303) within a sputtering chamber (e.g., 302) providing a controlled epitaxial growth environment.

At substep 403B, at least one supply line (e.g., 308A) provides at least one gas (e.g., 310A and/or 301B) from a gas source into the sputtering chamber (e.g., 302), and pressure within the chamber is controlled via a pressure control system (e.g., 314). In implementations, the gas is argon, or another inert gas. In implementations, oxygen is also fed into the sputtering chamber through a secondary supply line (e.g., 308B).

At substep 403C, a target material from a sputter gun is bombarded by energetic ions from a plasma via a radio frequency (RF) or direct current (DC) bias, causing the target material atoms (e.g., 306) to be ejected and deposited on the substrate (e.g., 304) for a period of time based on a desired thickness of the deposited target material. Existing off-axis sputtering techniques may be used to implement steps 403A-403C.

Optionally at 404, at least one anode (e.g., 203 or 213A, 213B) is formed on a surface of the epitaxial p-type spinel layer (e.g., 202 or 212A, 212B). See FIGS. 2A and 2B, for example.

Optionally, at 405, a cathode (e.g., 204 or 214) is formed on a surface of the Ga₂O₃ substrate (e.g., 201 or 211). See FIGS. 2A and 2B, for example. Existing electrode forming methods may be utilized at steps 404 and 405 in accordance with embodiments of the invention.

Optionally, at 406, a gate electrode (e.g., 215) is formed over the Ga₂O₃ substrate (e.g., 211) and the p-type spinel epitaxial layers (e.g., 212A, 212B). In implementations, the gate electrode 215 comprises a gate oxide layer (e.g., 216) in contact with the Ga₂O₃ substrate and the p-type spinel epitaxial layer (e.g., 212A, 212B), and a metal layer (e.g., 217) formed on a surface of the gate oxide layer. See FIG. 2B, for example.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of manufacturing spinel structures comprising:
depositing, via off-axis sputtering, an epitaxial layer of p-type spinel on a gallium oxide (Ga₂O₃) substrate, thereby creating a p-n heteroepitaxial interface between the p-type spinel and the Ga₂O₃ substrate.

2. The method of claim 1, wherein the p-type spinel is selected from the group consisting of: zinc gallate (ZnGa₂O₄), zinc cobalt oxide (ZnCo₂O₄), chromium manganese oxide (Cr₂MnO₄), magnesium aluminate (MgAl₂O₄), and zinc rhodium oxide (Zn Rh₂O₄).

3. The method of claim 1, wherein the p-type spinel is chromium manganese oxide (Cr₂MnO₄).

4. The method of claim 1, wherein the chromium manganese oxide (Cr₂MnO₄) is doped with lithium (Li) or chromium (Cr).

5. The method of claim 1, wherein the epitaxial layer has a thickness of between 5 nm and 500 nm.

6. The method of claim 1, wherein the gallium oxide (Ga₂O₃) substrate has a thickness between 100 μm and 600 μm.

7. The method of claim 1, wherein the off-axis sputtering is performed in an argon and oxygen atmosphere.

8. A spinel and gallium oxide (Ga₂O₃) p-n heteroepitaxial interface comprising:
an epitaxial layer of p-type spinel growth directly on a surface of a gallium oxide (Ga₂O₃) substrate via off-axis sputtering.

9. The spinel and gallium oxide (Ga₂O₃) p-n heteroepitaxial interface of claim 8, wherein the p-type spinel is selected from the group consisting of: zinc gallate (ZnGa₂O₄), zinc cobalt oxide (ZnCo₂O₄), chromium manganese oxide (Cr₂MnO₄), magnesium aluminate (MgAl₂O₄), and zinc rhodium oxide (Zn Rh₂O₄).

10. The spinel and gallium oxide (Ga₂O₃) p-n heteroepitaxial interface of claim 9, wherein the p-type spinel is chromium manganese oxide (Cr₂MnO₄).

11. The spinel and gallium oxide (Ga₂O₃) p-n heteroepitaxial interface of claim 10, wherein the chromium manganese oxide (Cr₂MnO₄) is doped with lithium (Li) or chromium (Cr).

12. The spinel and gallium oxide (Ga₂O₃) p-n heteroepitaxial interface of claim 8, wherein the epitaxial layer has a thickness of between 5 nm and 500 nm.

13. The spinel and gallium oxide (Ga₂O₃) p-n heteroepitaxial interface of claim 8, wherein the gallium oxide (Ga₂O₃) substrate has a thickness between 100 μm and 600 μm.

14. A semiconductor device comprising:
a gallium oxide (Ga₂O₃) substrate;
a p-type spinel epitaxial layer formed directly on a surface of the Ga₂O₃ substrate, thereby forming a p-n heteroepitaxial interface; and
electrodes.

15. The semiconductor device of claim 14, wherein the p-type spinel is selected from the group consisting of: zinc gallate (ZnGa₂04), zinc cobalt oxide (ZnCo₂O₄), chromium manganese oxide (Cr₂MnO₄), magnesium aluminate (MgAl₂O₄), and zinc rhodium oxide (Zn Rh₂O₄).

16. The semiconductor device of claim 15, wherein the p-type spinel is chromium manganese oxide (Cr₂MnO₄).

17. The semiconductor device of claim 16, wherein the chromium manganese oxide (Cr₂MnO₄) is doped with lithium (Li) or chromium (Cr).

18. The semiconductor device of claim 14, wherein the semiconductor device is a transistor.

19. The semiconductor device of claim 14, wherein the epitaxial layer has a thickness of between 5 nm and 500 nm.

20. The semiconductor device of claim 14, wherein the gallium oxide (Ga₂O₃) substrate has a thickness between 100 μm and 600 μm.
